(19) United States
(12) Patent Application Publication
(10) Pub. No.: US 2002/0170831 A1
(43) Pub. Date: Nov. 21, 2002

(54) Apparatus and method for separation of molecules and movement of fluids

(76) Inventors: Philip John Roeth, Castle Hills (AU); Steven Anthony Botto, Rydalmere (AU); Benjamin John Curley, Sutherland (AU); Chenicheri Hariharan Nair, Old Greenwich, CT (US)

Correspondence Address: James D. Jacobs, Esq., Baker & McKenzie, 805 Third Avenue, New York, NY, 10022, US

(21) Appl. No.: 10/029,026

(22) Filed: Dec. 21, 2001

(30) Foreign Application Priority Data
Dec. 21, 2000 (AU) PR 2224

(51) Int. Cl. C25C 7/00; C25B 9/00; C30B 30/02; C30B 7/12

(52) U.S. Cl. 205/770; 204/252

(57) ABSTRACT

An electrophoresis apparatus comprising: a first electrode in a first electrode zone; a second electrode in a second electrode zone, the first electrode disposed relative to the second electrode so as to be adapted to generate an electric field in an electric field area therebetween upon application of an electric potential between the first and second electrodes; a first membrane disposed in the electric field area; a second membrane disposed between the first electrode zone and the first membrane so as to define a first interstitial volume therebetween; wherein at least one membrane being a barrier capable of controlling substantial bulk movement of liquid under the influence of an electric field; means adapted to provide fluids to the electrode zone and the interstitial volume, wherein one of the fluids contains a sample constituent, and wherein upon application of the electric potential, liquid is caused to move from the sample constituent through at least one membrane to an adjacent electrode zone and at least one membrane prevents substantial bulk movement of liquid into the sample.

### BACKGROUND OF THE INVENTION

The present invention relates to method and apparatus for the separation of compounds, particularly macromolecules, where bulk movement of liquids can be managed.

Membrane-based electrophoresis is a new technology originally developed for the separation of macromolecules such as proteins, nucleotides and complex sugars. The process provides a high purity, scalable separation that is faster, cheaper and higher yielding than current methods of macromolecule separation and offers the potential to concurrently purify and detoxify macromolecule solutions.

In one form, the technology is bundled into a cartridge comprising a number of membranes housed in a system which allows separation of compounds by charge and/or molecular mass. The system can also concentrate and desalt/dialyze at the same time. The multimodal nature of the system allows this technology to be used in a number of other areas especially in the production of biological components for medical use. The structure of the membranes may be configured so that biological contaminants can also be removed at the point of separation—a task which is not currently available in the biotechnology industry and which adds to the cost of production through time delays and due to the complexity of the task. The transfer of liquid from on area to another, through a porous membrane, under electrophoretic conditions, is called electro-endo-osmosis (EEO). Electro-endo-osmosis is a natural occurrence with membrane-based electrophoresis technology and its management can result in the increase of product recovery, decrease in run times and increase in the concentration of samples. These improvements can be achieved by maintaining the concentration of the target molecule, in a specific steam, by managing the extent of bulk liquid transfer. One method to manage electro-endo-osmosis was via electro-osmosis, where an external power source alters the rate of a system undergoing osmosis or endo-osmosis. The impact of large volume increase is potentially more serious in the scale-up use of the system. Control of electro-endo-osmosis would contribute significantly to cost reduction and efficiencies in plant maintenance. The ability to concentrate samples without adversely affecting activity, functionality, quantity would be useful.

The present inventors have now developed a modification of the membrane-based electrophoresis technology to assist in the management of bulk liquid transfer/endo-osmosis.

### SUMMARY OF THE INVENTION

In accordance with the present invention, there is provided a membrane-based electrophoresis technology to assist in the management of bulk liquid transfer/endo-osmosis.

Further, in accordance with the present invention, there is provided an electrophoresis apparatus comprising:

a first electrode in a first electrode zone;

a second electrode in a second electrode zone, wherein the second electrode is disposed relative to the first electrode so as to be adapted to generate an electric field in an electric field area therebetween upon application of a selected electric potential between the first and second electrodes;

a first membrane disposed in the electric field area;

a second membrane disposed between the first electrode zone and the first membrane so as to define a first interstitial volume therebetween, wherein the first interstitial volume is separated from the first and second electrode zones by the first and second membranes, and wherein at least one of the membranes is a barrier membrane capable of controlling substantial bulk movement of liquid under the influence of an electric field; and

means adapted to communicate fluids to the first electrode zone, the second electrode zone, and the first interstitial volume wherein at least one of the fluids contains a sample constituent;

wherein the application of the selected electric potential causes at least one of at least a portion of any liquid within the sample constituent to migrate through at least one membrane into an adjacent electrode zone, and at least a portion of the sample constituent to migrate through at least one membrane into the first interstitial volume, and wherein the at least one barrier membrane controls substantial bulk movement of liquid into and out of the first interstitial volume so as to obtain at least a partially concentrated product in the first interstitial volume.

The apparatus suitably further comprises means adapted to receive a selected voltage and means adapted to apply a selected electric potential corresponding thereto across at least the electric field area. In this form, a power supply is provided or integrated with the apparatus. Typically, the apparatus is connected to an external power supply by any suitable electrical connector means.

In use, a sample is placed in the first interstitial volume (also called stream 1), buffer or solvent is provided to the electrode zones, an electric potential is applied to the electric field area causing movement of water out of the sample to the an adjacent electrode zone. The sample is thereby concentrated by driving liquid out of the sample. The barrier membrane substantially prevents bulk movement of liquid into the sample and the electrophoresis process causes water and salts to move out of the sample.

It is also feasible to place sample in one (or both) of the electrode zones and cause movement of one or more a compounds from the sample into the adjacent interstitial volume during the application of the voltage potential.

Further, in accordance with the present invention, there is provided an electrophoresis apparatus comprising:

a first electrode in a first electrode zone;

a second electrode in a second electrode zone, wherein the second electrode disposed relative to the first electrode so as to be adapted to generate an electric field in an electric field area therebetween upon application of a selected electric potential between the first and second electrodes;

a first membrane disposed in the electric field area;

a second membrane disposed between the first electrode zone and the first membrane so as to define a first interstitial volume therebetween;

a third membrane disposed between a second electrode zone and the first membrane so as to define a second interstitial volume therebetween, wherein the first interstitial volume is separated from the first electrode zone by the second membrane and the second interstitial volume is separated from the second electrode zone by the third membrane, and wherein at least one of the membranes is a barrier membrane capable of controlling substantial bulk movement of liquid under the influence of an electric field; and

means adapted to communicate fluids to the first electrode zone, the second electrode zone, the first interstitial volume, and the second interstitial volume, wherein at least one of the fluids contains a sample constituent; wherein the application of the selected electric potential causes at least one of at least a portion of any liquid within the sample constituent to migrate through at least one membrane into an adjacent electrode zone, and at least a portion of the sample constituent to migrate through at least one membrane into at least one of the interstitial volumes, and wherein the at least one barrier membrane controls substantial bulk movement of any liquid into and out of at least one of the interstitial volumes so as to obtain at least a partially concentrated product in at least one of the interstitial volumes.

The apparatus suitably further comprises means adapted to receive a selected voltage and means adapted to apply a selected electric potential corresponding thereto across at least the electric field area. In this form, a power supply is provided or integrated with the apparatus. Typically, the apparatus is connected to an external power supply by any suitable electrical connector means.

Preferably, sample and liquid are passed through heat exchangers to remove heat produced by the apparatus during electrophoresis.

Still further, in accordance with the present invention, there is provided an electrophoresis system comprising:

a first electrode in a first electrode zone;

a second electrode in a second electrode zone, wherein the second electrode disposed relative to the first electrode so as to be adapted to generate an electric field in a first electric field area therebetween upon application of a first selected electric potential between the first and second electrodes;

a first membrane disposed in the first electric field area;

a second membrane disposed between the first electrode zone and the first membrane so as to define a first interstitial volume therebetween;

a third membrane disposed between a second electrode zone and the first membrane so as to define a second interstitial volume therebetween, wherein the first interstitial volume is separated from the first electrode zone by the second membrane and the second interstitial volume is separated from the second electrode zone by the third membrane;

means adapted to communicate fluids to the first electrode zone, the second electrode zone, the first interstitial volume, and the second interstitial volume, wherein at least one of the fluids contains a sample constituent, wherein the application of the first selected electric potential causes at least a portion of the sample constituent to migrate through at least one membrane into at least one of the interstitial volumes to form a partially separated sample;

a third electrode in a third electrode zone;

a fourth electrode in a fourth electrode zone, wherein the third electrode disposed relative to the fourth electrode so as to be adapted to generate an electric field in a second electric field area therebetween upon application of a second selected electric potential between the third and fourth electrodes;

a fourth membrane disposed in the second electric field area;

a fifth membrane disposed between the third electrode zone and the fourth membrane so as to define a third interstitial volume therebetween, wherein the third interstitial volume is separated from the third and fourth electrode zones by the fourth and fifth membranes, wherein at least one of the fourth and fifth membranes is a barrier membrane capable of controlling substantial bulk movement of liquid under the influence of an electric field; and

means adapted to communicate fluids to the third electrode zone, the fourth electrode zone, and the third interstitial volume, wherein at least one of the fluids contains at least a partially separated sample from at least one of the first and second interstitial volumes, at least a portion of any liquid within the first partially concentrated product to migrate through at least one membrane into an adjacent electrode zone, and at least a portion of the first partially concentrated product to migrate through at least one membrane into third the interstitial volumes, and wherein the at least one barrier membrane controls substantial bulk movement of any liquid into and out of the third interstitial volumes so as to obtain at least a second partially concentrated product in the third interstitial volume.

The apparatus further comprises means adapted to receive a first selected voltage and means adapted to apply a first selected electric potential corresponding thereto across the first electric field area; and means adapted to receive a second selected voltage and means adapted to apply a second selected electric potential corresponding thereto across the second electric field area. In this form, one or more power supplies is provided or integrated with the apparatus. Typically, the apparatus is connected to a external power supply by any suitable electrical connector means such that two separate electric potentials can be applied.

Preferably, sample and liquid are passed through heat exchangers to remove heat produced by the apparatus during electrophoresis.

Gradiflow™ is a trade mark owned by Gradipore Limited, Australia.

Throughout this specification, unless the context requires otherwise, the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

Any discussion of documents, acts, materials, devices, articles or the like which has been included in the present specification is solely for the purpose of providing a context for the present invention. It is not to be taken as an admission that any or all of these matters form part of the prior art base or were common general knowledge in the field relevant to the present invention as it existed in Australia before the priority date of each claim of this application.

These and other aspects of the invention will be understood by one skilled in the art upon reading and understanding the specification.

### BRIEF DESCRIPTION OF THE DRAWINGS

FIG. 1 is a schematic diagram of a first embodiment of the present invention.

FIG. 1A shows an arrangement of electrodes, electrode zones and interstitial volume.

FIG. 1B shows positioning of two membranes in relation to electrodes.

FIG. 2 is a schematic diagram of a second embodiment of the present invention.

FIG. 2A shows an arrangement of electrodes, electrode zones and first and second interstitial volumes.

FIG. 2B shows positioning of three membranes in relation to electrodes.

FIG. 3 is a schematic diagram of a third embodiment of the present invention.

FIG. 3A shows an arrangement of electrodes, electrode zones and first, second and third interstitial volumes.

FIG. 3B shows positioning of five membranes in relation to two sets of electrodes.

FIG. 4 shows PAGE of CTA calibration experiments.

FIG. 5 shows endo-osmosis rates with CTA membranes.

FIG. 6 shows comparison of CTA orientation and the endo-osmotic rate.

FIG. 7 shows rate of volume removal due to electro-endo-osmosis using CTA membranes.

FIG. 8 shows bovine serum albumin (BSA) recovery with voltage change.

FIG. 9 shows rate of volume removal due to electro-endo-osmosis with PVA1 membranes.

FIG. 10 shows rate of volume removal due to electro-endo-osmosis

FIG. 11 shows plumbing of two apparatus incorporating a stream 1 concentrator machine for the management of endo-osmosis.

FIG. 12 shows comparison of endo-osmotic rate and percentage fibrinogen recovery.

FIG. 13 shows PAGE analysis of simultaneous separation and concentration of bovine Prion Protein (PrP) of bovine brain homogenate using membrane-based electrophoresis technology and PVA1 membrane. Part A: SDS-PAGE of the samples from the electrophoresis run; Part B: Western blot of the samples from the electrophoresis run using anti-PrP R029 (Prionics, Switzerland). S1₀ Stream 1 at time 0 minutes; S1₁₈₀ Stream 1 at time 180 minutes; S2₀ Stream 2 at time 0 minutes; S2₁₈₀ Stream 2 at time 180 minutes.

FIG. 14 shows a first configuration of the present invention which allows for simultaneous concentration and partial purification of samples.

FIG. 15 shows PAGE analysis of concentration of the feed stream with partial purification.

FIG. 16 shows PAGE analysis of stream containing removed contaminants.

FIG. 17 shows a second configuration of the present invention which allows for simultaneous concentration and purification of target protein with contaminant depletion of feed stream and EEO control of feed stream volume.

FIG. 18 shows PAGE analysis of feed stream concentrated during the course of the experiment, but was also depleted of contaminant proteins. Contaminant depletion enhances the transfer of the target protein to the product stream by simplifying the contents of the feed stream.

FIG. 19 shows PAGE analysis of target protein purified and concentrated into stream 2. The transfer rate to the product stream was maintained by concentrating the feed stream. As the concentration of target in the feed stream was depleted, the transfer rate slowed unless the feed stream volume was reduced. This volume reduction could result in interference from the increased contaminant concentration unless the feed stream is also depleted of contaminants.

FIG. 20 shows a schematic diagram of a third configuration of present invention wherein the target is transferred to the second stream and the feed stream is concentrated.

FIG. 21 shows a schematic diagram of a fourth configuration of the present invention which allows for the transfer of product to stream 2 while concentrating and optionally purifying stream 1 to the buffer stream or an optional third stream.

FIG. 22 shows a schematic diagram of a fifth configuration of the present invention which uses EEO membranes on either side of the feed stream to enhance concentration effect, with MMCO of EEO membranes selected to allow for contaminant transfer away from the target protein which is retained and concentrated in the center feed stream.

FIG. 23 shows a schematic diagram of a sixth configuration of the present invention which uses two membrane-based electrophoresis instruments for separate concentrating and purifying functions.

FIG. 24 shows a schematic diagram of a seventh configuration of the present invention wherein the target remains in the feed stream and is concentrated.

### DETAILED DESCRIPTION OF THE INVENTION

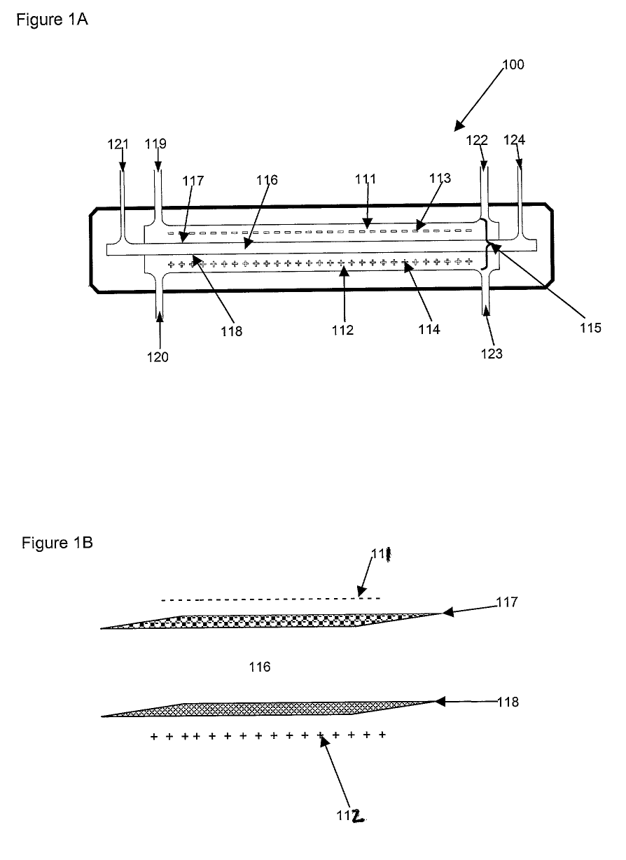

The present invention is directed to a membrane-based electrophoresis technology to assist in the management of bulk liquid transfer/endo-osmosis. In one embodiment as shown in FIG. 1A, the electrophoresis apparatus 100 is comprised of first and second electrode zones 111 and 112, wherein the first and second electrode zones each contain an electrode 113 and 114. The second electrode zone 112 is disposed relative to the first electrode zone 111 so as to be adapted to generate an electric field in an electric field area 115 therebetween upon application of a selected electric potential between the electrodes 112 and 113. The apparatus 110 is further comprised of a first interstitial volume 116 defined by a first membrane 117 disposed in the electric field area 115 and a second membrane 118 disposed between the first electrode zone 111 and the first membrane 117. The first interstitial volume 115 is separated from the first and second electrode zones 111 and 112 by the first and second membranes 117 and 118. At least one of the membranes is a barrier membrane capable of controlling substantial bulk movement of liquid under the influence of an electric field.

In FIG. 1B, the barrier membrane is depicted as the first membrane 117. It will be appreciated that the second membrane 118 can form the barrier membrane. In FIG. 1, the first electrode 113 is depicted as a cathode and the second electrode 114 is depicted as an anode for convenience only. The polarity of the electrodes can be reversed where the first electrode 113 is an anode and the second electrode 114 is a cathode.

The apparatus 110 includes means 119, 120, and 121 for communicating fluids to the first electrode zone 111, the second electrode zone 112, and the first interstitial volume 116, wherein at least one of the fluids contains a sample constituent. The apparatus 100 suitably further includes means for applying a selected electric potential across at least the electric field area. The application of the selected electric potential causes at least one of at least a portion of any liquid within the sample constituent to migrate through at least one membrane into an adjacent electrode zone, and at least a portion of the sample constituent to migrate through at least one membrane into the first interstitial volume. The barrier membrane(s) controls substantial bulk movement of liquid into and out of the first interstitial volume such that a partially concentrated product is collected and/or remains in the first interstitial volume.

In use, a sample is placed in the first interstitial volume 116 (also called stream 1), buffer or solvent is provided to the electrode zones 111 and 112, an electric potential is applied to the electric field area causing movement of water out of the sample to the an adjacent electrode zone. The sample is thereby concentrated by driving liquid out of the sample. The barrier membrane substantially prevents bulk movement of liquid into the sample and the electrophoresis process causes water and salts to move out of the sample.

It is also feasible to place sample in one (or both) of the electrode zones and cause movement of one or more a compounds from the sample into the adjacent interstitial volume during the application of the voltage potential.

The apparatus further suitably comprises means 122, 123, and 124 for communicating fluids, sample constituent, and or product from the electrode zones and the interstitial volume.

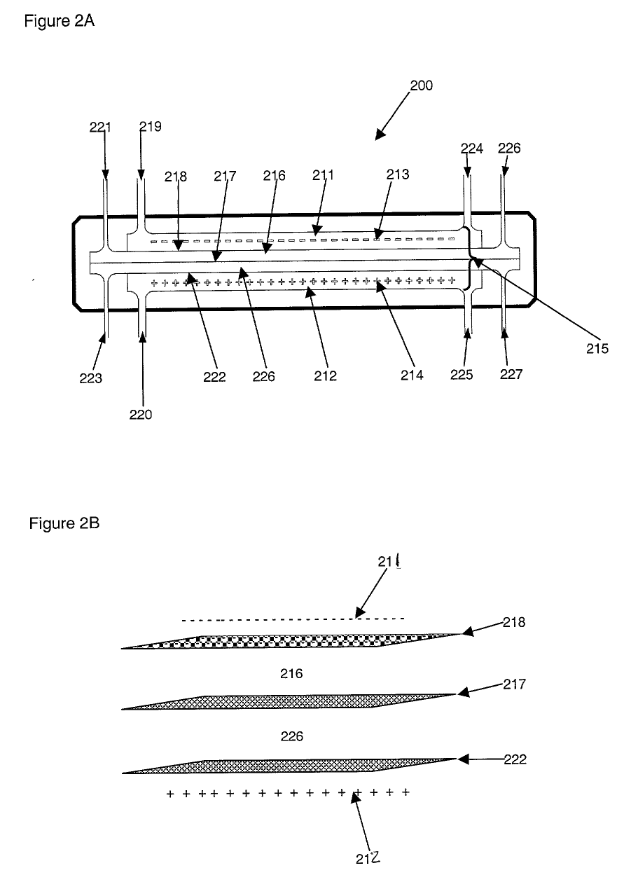

In another embodiment as shown in FIG. 2A, the electrophoresis apparatus 210 is comprised of first and second electrode zones 211 and 212, wherein the first and second electrode zones each contain an electrode 213 and 214. The second electrode zone 212 is disposed relative to the first electrode zone 211 so as to be adapted to generate an electric field in an electric field area 215 therebetween upon application of a selected electric potential between the electrodes 213 and 214. The apparatus 210 has first and second interstitial volumes 216 and 226. The first interstitial volume 216 is defined by a first membrane 217 disposed in the electric field area 215 and a second membrane 218 disposed between the first electrode zone 211 and the first membrane 217. The second interstitial volume 226 is defined by the first membrane 217 and a third membrane 222 disposed between the first membrane 217 and the second electrode zone 212. The first interstitial volume 216 is separated from the first electrode zone 211 by the second membrane 218 and the second interstitial volume 226 is separated from the second electrode zone 212 by the third membrane 222. At least one of the first, second, and third membranes 217, 218, and 222 is a barrier membrane capable of controlling substantial bulk movement of liquid under the influence of an electric field.

In FIG. 2B, the barrier membrane is depicted as the second membrane 218. It will be appreciated that the first membrane 217 or third membrane 222 can form the barrier membrane. In FIG. 2, the first electrode 213 is depicted as a cathode and the second electrode 214 is depicted as an anode for convenience only. The polarity of the electrodes can be reversed where the first electrode 213 is an anode and the second electrode 214 is a cathode.

The apparatus includes means 219, 220, 221 and 223 for communicating fluids to the electrode zones 211 and 212 and interstitial volumes 216 and 226 and at least one of the fluids contains a sample constituent. The apparatus 200 suitably also includes means for applying a selected electric potential across at least the electric field area. The application of the electric potential causes at least one of at least a portion of any liquid within the sample constituent to migrate through at least one membrane into an adjacent electrode zone, and at least a portion of the sample constituent to migrate through at least one membrane into at least one of the interstitial volumes. The barrier membrane(s) controls substantial bulk movement of liquid into and out of the interstitial volumes such that a partially concentrated product is collected and/or remains in at least one of the interstitial volumes.

In use, a sample is placed in the first interstitial volume (also called stream 1), buffer or solvent is provided to the electrode zones and the second interstitial volume (stream 2), an electric potential is applied to the electric field area causing at least one constituent in the sample to move to buffer/solvent in the adjacent electrode zone or to the adjacent second interstitial volume. The barrier membrane substantially prevents movement of liquid into the sample.

It will be appreciated that the order of interstitial volumes can be reversed where a sample is placed in the second interstitial volume (stream 2), buffer or solvent is provided to the electrode zones and the first interstitial volume, an electric potential is applied to the electric field area causing at least one constituent in the sample to move to the adjacent electrode zone or to the adjacent first interstitial volume (stream 1).

It is also feasible to place a sample in one (or both) of the electrode zones and cause movement of one or more compounds into one or more of the interstitial volumes during the application of the voltage potential.

The apparatus further suitably comprises means 222, 225, 226 and 227 for communicating fluids, sample constituent, and or product from the electrode zones and the interstitial volumes.

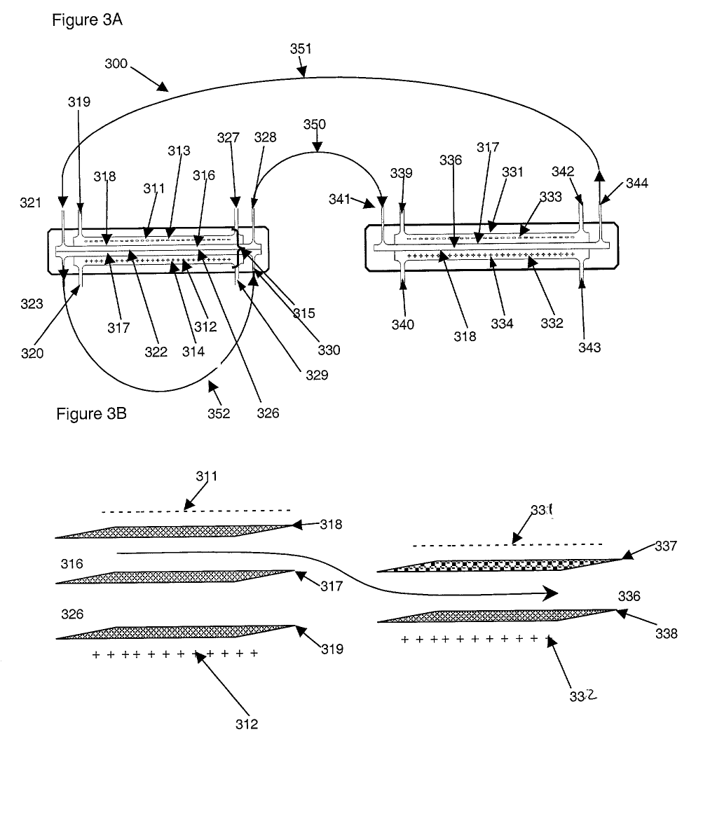

In another embodiment as shown in FIG. 3, the electrophoresis apparatus 300 is comprised of first and second electrode zones 311 and 312, wherein the first and second electrode zones each contain an electrode 313 and 314. The second electrode zone 312 is disposed relative to the first electrode zone 311 so as to be adapted to generate an electric field in an electric field area therebetween upon application of a selected electric potential between the electrodes 311 and 312. The apparatus 300 has first and second interstitial volumes 316 and 326. The first interstitial volume 316 is defined by a first membrane 317 disposed in the electric field area and a second membrane 318 disposed between the first electrode zone 311 and the first membrane 317. The second interstitial volume 326 is defined by the first membrane 317 and a third membrane 322 disposed between the first membrane 317 and the second electrode zone 312. The first interstitial volume 316 is separated from the first electrode zone 311 by the second membrane 318. The second interstitial volume 326 is separated from the second electrode zone 312 by the third membrane 322.

The apparatus includes means 319, 320, 321, and 323 for communicating fluids to the electrode zones and interstitial volumes and at least one of the fluids contains a sample constituent. The apparatus suitably also includes means for applying a selected electric potential across at least the electric field area. The application of the electric potential causes at least one of at least a portion of any liquid within the sample constituent to migrate through at least one membrane into an adjacent electrode zone, and at least a portion of the sample constituent to migrate through at least one membrane into at least one of the interstitial volumes. The barrier membrane(s) controls substantial bulk movement of liquid into and out of the interstitial volumes such that a partially concentrated product is collected and/or remains in at least one of the interstitial volumes.

The apparatus 300 further includes third 331 and fourth electrode zones 332, wherein the third and fourth electrode zones each contain an electrode 333 and 334. The fourth electrode zone 332 is disposed relative to the third electrode zone 331 so as to be adapted to generate an electric field in an electric field area therebetween upon application of a selected electric potential between the electrodes. The apparatus 300 is further comprised of a third interstitial volume 336 defined by a fourth membrane 327 disposed in the electric field area and a fifth membrane 338 disposed between the third electrode zone 331 and the fourth membrane 337. The third interstitial volume 336 is separated from the third and fourth electrode zones 331 and 332 by the fourth and fifth membranes 337 and 338. At least one of the membranes is a barrier membrane capable of controlling substantial bulk movement of liquid under the influence of an electric field.

In FIG. 3B, the first electrode 313 is depicted as a cathode, the second electrode 314 is depicted as an anode, third electrode 333 is depicted as a cathode and the fourth electrode 334 as an anode for convenience only. The polarity of the electrodes can be reversed where the first and third electrodes 313 and 333 are anodes and the second and fourth electrodes 314, and 334 are cathodes. Similarly, the first and fourth electrodes 313 and 334 are anodes and the second and third electrodes 314 and 333 are cathodes.

The apparatus includes means 339, 340, and 341 for communicating fluids to the third electrode zone, the fourth electrode zone, and the third interstitial volume and at least one of the fluids contains a partially concentrated product from at least one of the first and second interstitial volumes. The apparatus further includes means for applying a selected electric potential across at least the electric field area. The application of the selected electric potential causes at least one of at least a portion of any liquid within the sample constituent to migrate through at least one membrane into an adjacent electrode zone, and at least a portion of the first partially concentrated product to migrate through at least one membrane into the third interstitial volume. The barrier membrane(s) controls substantial bulk movement of liquid into and out of the third interstitial volume such that a second partially concentrated product is collected and/or remains in the third interstitial volume.

FIG. 3A shows the connection of two apparatus to form the apparatus according to the third aspect of the present invention. The first apparatus carries out some form of purification or separation of a sample while the second apparatus concentrates the partially purified sample. It is also feasible to have the first apparatus configured according to the second embodiment of the present invention where at least one of the first, second or third membranes is also a barrier membrane capable of controlling substantial bulk movement of liquid under the influence of an electric field. In this form, the flow of fluid into or out of the sample constituent is suitably also controlled.

The apparatus further suitably comprises means 327, 328, 329, and 330 for communicating fluids, sample constituent, and or product from the first electrode zone, second electrode zone, the first interstitial volume, and the second interstitial volume. The apparatus further suitably comprises means 342, 343, and 344 for communicating fluids, sample constituent, and or product from the third electrode zone, fourth electrode zone, and the third interstitial volume.

The apparatus also includes means 350 and 351 for communicating fluids, sample constituents, and/or products between the two apparatus used in this embodiment. After being processed in the first apparatus, the partially concentrated product is transferred to the second apparatus as shown by 350. After being processed in the second apparatus, the product may be transferred back to the first apparatus for further treatment or processing as shown by 351. Further, the apparatus includes means 352 for transferring fluids, sample constituent, and/product between fluid communications means 323 and 328.

Preferably, the at least one barrier membrane is an inducible electro-endo-osmotic membrane.

In another preferred form, some of the membranes are electrophoresis separation membranes and other membranes are restriction membranes having defined pore sizes. Preferably, the restriction membranes are positioned between the electrode zones and an adjacent interstitial volume. At least one of the restriction membranes is the inducible electro-endo-osmotic membrane which controls the substantial bulk movement of liquid under the influence of an electric field.

The electrophoresis separation membranes are preferably made from polyacrylamide and have a molecular mass cut-off of at least about 3 kDa. The molecular mass cut-off of the membrane will depend on the sample being processed, the other molecules in the sample mixture, and the type of separation carried out.

At least one restriction membrane is also preferably formed from polyacrylamide. The molecular mass cut-off of the restriction membrane will depend on the sample being processed, the other molecules in the sample mixture, and the type of separation carried out.

The inducible electro-endo-osmotic membrane is preferably a cellulose tri-acetate (CTA) membrane. It will be appreciated that the inducible electro-endo-osmotic membrane is suitably formed from any other suitable membrane material such as poly(vinyl alcohol) cross-linked with glutaraldehyde (PVA1+glut).

The present inventors have found that a CTA membrane having a nominal molecular mass cut-off of 5, 10 or 20 kDa are particularly suitable for use in the apparatus according to the present invention. It will be appreciated that other molecular mass cut-offs would also be suitable for the present invention.

The first membrane is preferably an electrophoresis separation membrane comprised of polyacrylamide (PA) and having a defined molecular mass cut-off. Preferably, the electrophoresis separation membrane has a molecular mass cut-off from about 1 kDa to about 2000 kDa. The selection of the molecular mass cut-off of the separation membrane will depend on the sample being processed and the other molecules in the mixture. It will be appreciated, however, that other membrane chemistries or constituents can be used for the present invention.

At least one of the second and third membranes is a restriction membrane preferably formed from polyacrylamide and usually having a molecular mass cut-off less than the separation membrane, preferably from about 1 kDa to about 1000 kDa. The selection of the molecular mass cut-off of the restriction membrane will depend on the sample being processed and the size of the macromolecules to be removed. The restriction membrane can have the same molecular mass cut-off or different cut-off from that of the barrier membrane.

In one preferred form, the membranes forming the first and second interstitial volumes are provided as a cartridge or cassette positioned between the electrode zones of the apparatus. The configuration of the cartridge is preferably a housing with the first membrane positioned between the second and third membranes thus forming the required interstitial volumes.

The membranes may be formed as a multilayer or sandwich arrangement. The thickness of the membranes can have an effect on the separation or movement of compounds. It has been found that the thinner the membrane, the faster and more efficient movement occurs.

Preferably, the cartridge or cassette is removable from an electrophoresis apparatus adapted to contain or receive the cartridge.

The cartridge may also include one or more of the electrodes.

The electrode zones are supplied with suitable electrolyte or buffer solutions by any suitable pumping means. A sample to be processed is supplied directly to the first interstitial volume or second interstitial volume (if present) by any suitable pumping means.

Preferably, the zones and the interstitial volume(s) are configured to allow flow of the respective liquid/buffer and sample solutions forming streams. In this form, large volumes can be processed quickly and efficiently. The solutions are typically moved or recirculated through the zones and interstitial volume(s) from respective reservoirs by suitable pumping means. In a preferred embodiment, peristaltic pumps are used as the pumping means for moving the sample, buffers or liquids.

Electrode buffers or electrolytes and sample buffers are any suitable buffer or electrolyte. Examples include, but not limited to, Tris/Borate, Hepes/Imidazole, GABA/Acetic acid and Hepes/Histidine buffers.

The present invention is suitable for the separation or treatment of any compound capable of having a charge or a defined molecular mass. Examples include, but not limited to, biological compounds such as peptides, proteins, nucleic acids, and the like.

In one embodiment, electrode buffer, other buffers and sample solutions are cooled by any suitable means to ensure no inactivation of the micromolecules, compounds, macromolecules or other sample components occurs during the electrophoresis process and to maintain a desired temperature of the apparatus while in use.

Preferably, in order to collect and/or concentrate sample components, fluid in at least one of the volumes or streams containing any separated components or molecules is collected and replaced with suitable solvent to ensure that electrophoresis can continue in an efficient manner.

The distance between the electrodes has an effect on the separation or movement of sample constituents through the membranes. The shorter the distance between the electrodes, the faster the electrophoretic movement of constituents. A distance of about 6 mm has been found to be suitable for a laboratory scale apparatus. For scale up versions, the distance will depend on the number and type of separation membranes, the size and volume of the chambers for samples, buffers and separated products. Preferred distances would be in the order of about 6 mm to about 10 cm. The distance will also relate to the voltage applied to the apparatus.

The effect of the electric field is based on the equation:

e=V/d

(e=electric field, V=voltage, d=distance)

Therefore, the smaller the distance between the electrodes, the faster the separation. Preferably, the distance between the electrodes should decrease in order to increase electric field strength, thereby further improving transfer rates through the membranes.

Flow rate of sample/buffer/liquid has an influence on the separation of constituents. Rates of milliliters per minute up to liters per minute are used depending on the configuration of the apparatus and the nature and volume of the sample to be separated. Currently in a laboratory scale instrument, the preferred flow rate is about 20±5 mL/min. However, flow rates from about 0 mL/min to about 50,000 mL/min are used across the various separation regimes. The maximum flow rate is even higher, depending on the pumping means and size of the apparatus. The selection of the flow rate is dependent on the product to be transferred, efficiency of transfer, pre- and post-positioning with other applications.

Selection or application of the voltage and/or current applied varies depending on the separation. Typically up to several thousand volts are used but choice and variation of voltage will depend on the configuration of the apparatus, buffers and the sample to be separated. In a laboratory scale instrument, the preferred voltage is about 250 V. However, depending on transfer, efficiency, scale-up and particular method from about 0 V to about 5000 V are used. Higher voltages are also considered, depending on the apparatus and sample to be treated.

Optionally, the electric potential may be periodically stopped and/or reversed to cause movement of a constituent having entered a membrane to move back into the volume or stream from which it came, while substantially not causing any constituents that have passed completely through a membrane to pass back through the membrane.

Reversal of the electric potential is an option but another alternative is a resting period. Resting (a period without an electric potential being applied) is an optional step that can replace or be included before or after an optional electrical potential reversal. This resting technique can often be practiced for specific separation applications as an alternative or adjunct to reversing the potential.

In one particularly preferred embodiment, the electrodes are made of titanium mesh coated with platinum. It will be appreciated, however, that other materials and configurations can be used.

For convenience, the first interstitial volume or stream is called stream 1 and the second interstitial volume or stream is called stream 2. Typically, sample was placed in stream 1 and constituents caused to move through the separation membrane into stream 2.

In use, buffer or other suitable solvent is circulated through the electrode zones and the sample constituent is provided to at least one of the first and second interstitial volumes. When an electric potential or field is applied to the apparatus via the electrodes, some components in the sample will be caused to move through the membrane into the adjacent interstitial volume or an electrode zone. The inducible electro-endo-osmotic membrane prevents or controls substantial bulk liquid movement between the interstitial volume and electrode zone thereby preventing undesirable dilution of the sample or separated product during the separation process.

In one preferred form, two apparatus are connected in a manner so as to further control or prevent bulk movement of liquid into one or more of the interstitial volumes. The first apparatus is configured as shown in FIG. 2 with or without the barrier membrane and functions to separate one or more compounds of choice. The second apparatus is suitably configured as shown in FIG. 1 and allows for concentration of the separated compound. Preferably, the electric potential applied to each apparatus is under separate control. In one preferred form, the second interstitial volume of the first apparatus is in fluid communication with the first interstitial volume of the second apparatus. In use, after the compound to be separated is caused to move to the second interstitial volume of the first apparatus, it is then transferred to the first interstitial volume of the second apparatus which causes unwanted liquid to move out of the separated compound. This dual apparatus system functions as a further sample concentrator without the substantial loss of liquid or sample.

In another preferred form, two apparatus are connected in a manner so as to further control or prevent bulk movement of liquid into one or more of the interstitial volumes. The first apparatus is configured as shown in FIG. 2 with or without the barrier membrane and functions to separate one or more compounds of choice. The second apparatus is configured as shown in FIG. 1 and allows for concentration of the sample during the electrophoresis process. Preferably, the electric potential applied to each apparatus is under separate control. In this preferred form, the first interstitial volume of the first apparatus containing the sample is in fluid communication with the first interstitial volume of the second apparatus. In use, the sample is circulated between the two apparatus to remove or reduce liquid build-up caused during electrophoresis in the first apparatus. The compound to be separated is caused to move to the second interstitial volume of the first apparatus for collection. This dual apparatus system functions as a further sample concentrator without the substantial loss of liquid or sample.

In order that the present invention may be more clearly understood, examples of the present invention are described with reference to the preferred forms of the separation technology as described.

### EXAMPLES

The transfer of liquid from one area to another, through a porous membrane, is called endo-osmosis. Endo-osmosis is an issue with membrane-based electrophoresis technology and its management can increase product recovery, decrease run times and concentrate samples. One method to manage endo-osmosis is via electro-osmosis, where an external power source alters the rate of a system undergoing osmosis or endo-osmosis. In-order to identify a biocompatible membrane, cellulose tri-acetate (CTA) membranes were used for a series of dialysis experiments where CTA was identified as a high endo-osmotic membrane. Due to the high endo-osmotic rate of CTA, its role in managing endo-osmosis was investigated. Additional work was also done to investigate the endo-osmotic rate of PVA1 membranes.

The following parameters were investigated:

i) whether CTA endo-osmosis is voltage dependent;

ii) whether PVA1 endo-osmosis is voltage dependent;

iii) whether CTA endo-osmosis is pH dependent; and

iv) whether CTA be incorporated into membrane-based electrophoresis technology to improve yield, purification rates and/or act as a concentrator.

Materials

Membrane-based electrophoresis apparatus made by Gradipore Limited, Australia 5 kDa, 500 kDa, 700 kDa and 1500 kDa molecular mass cut-off polyacrylamide (PA) membranes (Gradipore)

5 kDa, 10 kDa and 20 kDa cellulose tri-acetate (CTA) membranes (Sartorius)

5% poly vinyl alcohol (PVA1) membrane (Gradipore Limited)

Bovine serum albumin (BSA) 67 kDa pI5, ovalbumin 45 kDa pI 4.2, trypsin inhibitor 14 kDa pI 4.7, and fibrinogen 330 kDa pI 5.5

### Example 1

### Calibration of the Molecular Mass Cut-Off of CTA Membranes

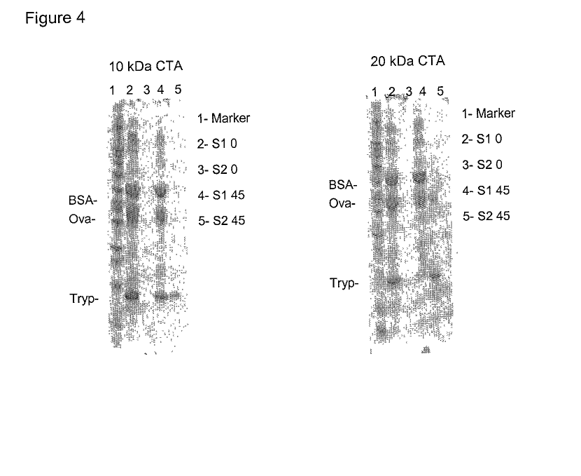

The molecular mass cut off for the 10 kDa and 20 kDa CTA membranes were determined for use in membrane-based electrophoresis technology. The 10 kDa and 20 kDa CTA membranes were used in separate purification runs where 3 mg/mL protein mixture (1 mg/mL of each—BSA, ovalbumin and trypsin inhibitor in TB pH 8.0) was placed in the stream 1 and separated with 250V for 45 min into the stream 2. A non-reduced PAGE of the 0 min stream 1 and 45 min stream 2 were run to determine the molecular mass cut-off of the 10 kDa and 20 kDa CTA membranes as shown in FIG. 4.

The results of the CTA calibration experiments (FIG. 4), suggested that the actual cut-off for the CTA membranes were 14 kDa for the 10 kDa membrane and 45 kDa for the 20 kDa CTA membrane. The 14 kDa molecular mass cut off of the 10 kDa CTA membrane was determined from the PAGE as only trypsin inhibitor (14 kDa) was observed after passing through the 10 kDa CTA membrane during the 45 min electrophoresis run. The 45 kDa molecular mass cut off of the 20 kDa CTA membrane was determined from the PAGE as trypsin inhibitor (14 kDa), ovalbumin (45 kDa) and a small quantity of BSA (67 kDa) passed through the 20 kDa CTA membrane during the 45 min electrophoresis run.

### Example 2

### Orientation of CTA membranes

CTA membranes were asymmetric. Therefore, to use CTA membranes for further experimentation, the orientation (shiny side up or down) and endo-osmotic rate of 5 kDa, 10 kDa and 20 kDa CTA membranes were analyzed. These parameters were investigated in two stream and single stream apparatus configurations in order to identify which configuration had the highest endo-osmotic rate. This involved recording volume variations every 5 min and comparing the amount of starting BSA (1 mg/mL) to the final amount of BSA.

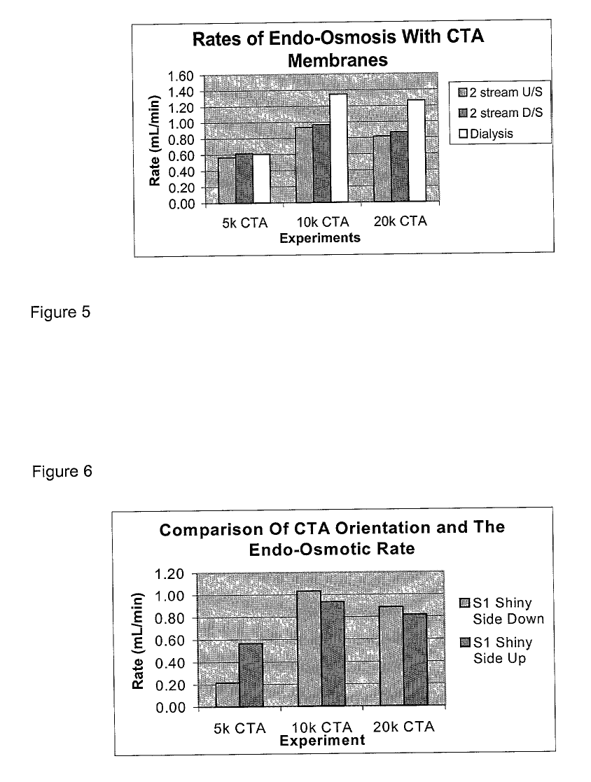

The experimental data suggested that the 5 kDa CTA membrane had the slowest endo-osmotic rate in both the standard and single steam configuration, compared to the other CTA membranes as shown in FIG. 5. The endo-osmotic rates for both the 10 kDa and 20 kDa membranes were comparably high, with the single stream configuration demonstrating a higher endo-osmotic rate than the standard configuration (FIG. 5). The 10 kDa CTA membrane had the highest endo-osmotic rate in both configurations compared to the 5 kDa and 20 kDa CTA membranes.

As the CTA membranes were asymmetric (a shiny side and a dull side) a comparison of the orientation was also conducted. The results indicated that the endo-osmotic rate of the shiny side up 5 kDa CTA membrane was higher than the shiny side down as shown in FIG. 6. However, for the 10 kDa and 20 kDa CTA membranes shiny side down performed slightly better than the shiny side up. Overall, the 10 kDa CTA membrane had a higher endo-osmotic rate.

In conclusion, single stream configuration of membrane-based electrophoresis technology using a 10 kDa CTA membrane, in either symmetry, produced the highest endo-osmotic rate. This provided the foundation for the remaining experimental procedures using CTA membranes. For consistency, all remaining CTA experiments were single stream configuration, using a 10 kDa shiny side up membrane.

### Example 3

### Endo-Osmosis and Voltage Using CTA Membranes

To determine whether endo-osmosis was voltage dependent, a series of experiments in which the volume change due to electro-osmosis were prepared. To investigate whether CTA endo-osmosis was voltage dependent, an electrophoresis apparatus was set-up in single stream configuration, with cooled TB pH 9.0 in the buffer tank, and a cartridge consisting of a polyacrylamide (PA) restriction membrane and a top CTA separating and, or volume control barrier membrane. Fifty mL of 1 mg/mL BSA was run through the cartridge in the stream 2 of the apparatus for 30 min. The change in volume was measured every 5 min and the concentration of the initial and final stream 2 were determined by spectrophotometry (A₂₈₀). The above experimental set-up was repeated from 0V to 300V (1A, 300W) at 50V increments.

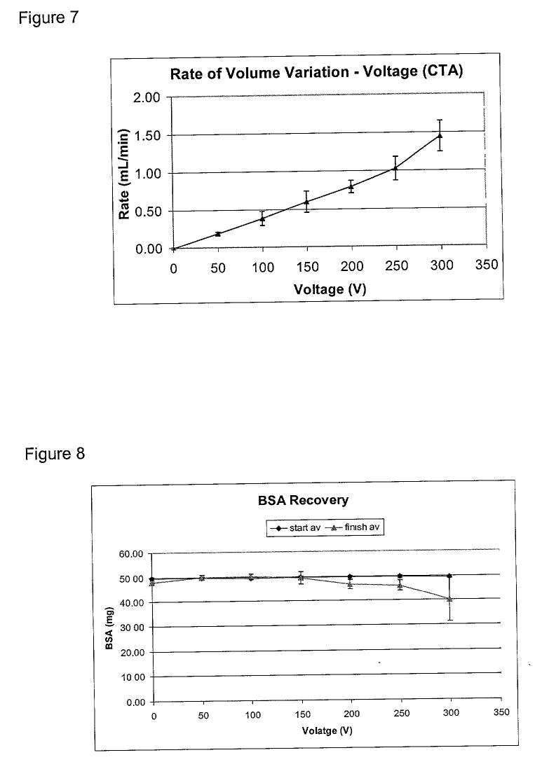

The experimental data showed that as the voltage increased, the rate of volume loss increased linearly as shown in FIG. 7. The results suggested that the endo-osmotic rate, in conjunction with CTA as a volume control barrier, can be managed by altering the voltage for procedures in which bulk liquid transfer is an issue. However, as the voltage increased, the amount of BSA recovered was reduced as shown in FIG. 8. The reduced recovery of BSA was attributed to the increased voltage forcing the BSA into the restriction PA membrane.

### Example 4

### Endo-Osmosis and Voltage Using PVA1 Membranes

To determine whether endo-osmosis was voltage dependent using PVA1 membranes, experiments were carried out using the method used for CTA membranes outlined in the section above.

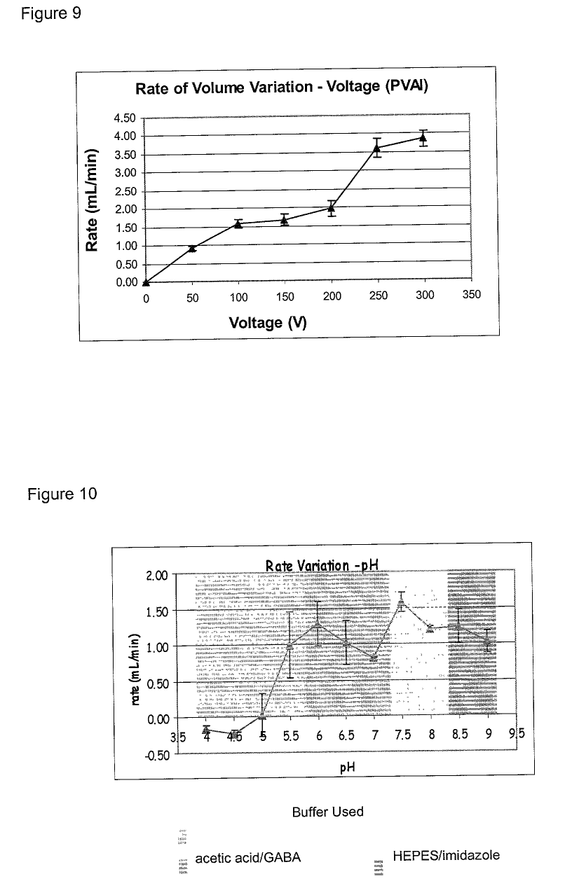

The experimental data showed that as the voltage was increased, the rate of volume reduction also increased as shown in FIG. 9. However, the correlation was not as linear as that achieved using the CTA membranes. Comparison of CTA and PVA1 electro-endo-osmosis rates using 200V on an apparatus in single stream configuration with BSA, resulted in a 4× increase in the electro-endo-osmosis rate when using PVA1, compared to CTA. There was no change in the electro-endo-osmosis rate when using PA membranes.

### Example 5

### Endo-Osmosis and pH Using CTA Membranes

To determine whether endo-osmosis was pH dependent, a series of experiments in which the volume reduction due to electro-endo-osmosis were compared. To investigate whether CTA endo-osmosis was pH dependent an electrophoresis apparatus was set-up in single stream configuration, with cooled TB pH 9.0 in the buffer tank, and a cartridge consisting of a bottom PA membrane restriction and a top CTA separating and, or volume control barrier membrane. Fifty mL of 1 mg/mL BSA was run through the cartridge in the stream 2 of the apparatus for 30 min at 250V (1A, 300W). The change in volume was measured every 5 min and the concentration of the initial and final stream 2 were determined by spectrophotometry (A₂₈₀). The above experimental set-up was repeated from pH 4.0 to pH 9.0, at pH 0.5 increments.

The experimental data suggested that as the pH increased, the rate of volume reduction increased as shown in FIG. 10. However, each buffer had its own variations, suggesting that pH dependent endo-osmosis rates may need to be determined for individual applications and buffer systems.

### Example 6

### Endo-Osmosis Management and Isolation of Fibrinogen

To test whether the endo-osmotic rate could be managed with a charged membrane, a procedure with a high endo-osmotic rate was studied. The procedure with a high endo-osmotic rate was the isolation of fibrinogen from cryo-precipitate. Isolating fibrinogen from cryo-precipitate typically resulted in the increase of the stream 1 volume by a factor of 5 to 8, with fluid being drawn from the stream 2 during the purification process. In order to test the effect of altering the accumulation of fluid in stream 1, fibrinogen was isolated from a stock cryo-precipitate (1:3 dilution cryo-precipitate stock solution was prepared and used as the starting material for all three methods), using four different methods.

Method 1

Standard isolation of fibrinogen using electrophoresis apparatus with a 700-1500-700%Da PA membrane cartridge, at 250V (1A, 300W). The buffer tank contained cooled TB pH 9.0, 30 mL 1:3 diluted cryo-precipitate stock solution was placed in stream 1, and 10 mL TB pH 9.0 in stream 2. The change in stream 1 volume was noted every 15 min, along with a spectrophotometry (OD₂₈₀) reading of the stream 2. Stream 2 was harvested every 30 min, the buffer replaced and the voltage reversed for 2 min (to de-foul the membrane).

Method 2

Similar to method 1, with the exception that the top restriction membrane (700 kDa PA membrane) was replaced with a 10 kDa CTA volume control barrier membrane.

Method 3

Two membrane-based electrophoresis apparatus 350 and 360 were used, with separate power supplies, attached together as shown in FIG. 11. Apparatus 1 350 was prepared and run as described in method 1 (note: the 700 kDa restriction membranes were replaced with 500 kDa restriction membranes), Apparatus 2 360, however, was configured as a single stream with a 5 kDa PA membrane (bottom) 10 kDa CTA membrane (top). Apparatus 2 was connected to stream 1 of apparatus 1 and functioned as a stream 1 concentrator, by managing the endo-osmotic rate with the separate power supply. From the data obtained from the voltage dependence experiments above, a voltage which matched the endo-osmotic rate of method 1 was chosen. The voltage of apparatus 2 was 250V (1A, 300W).

Method 4

Similar to method 1, with the exception that the top restriction membrane was replaced with a PVA1 membrane.

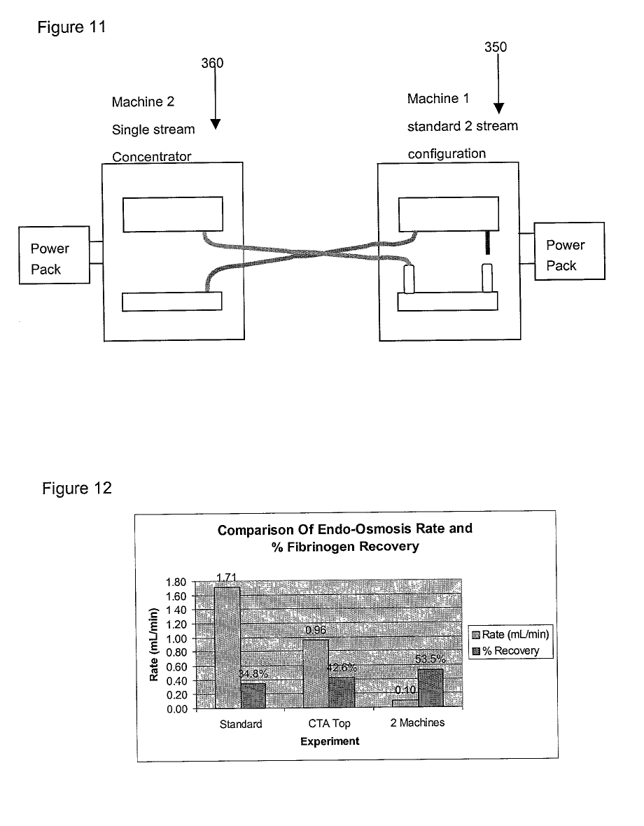

Using CTA during fibrinogen isolation was found to decrease the amount of endo-osmosis as shown in FIG. 12 by a factor of 2 (method 2) to a factor of 6 (method 3). Using a separate power supply and apparatus with a concentrator cartridge, the stream 1 endo-osmosis rate was maintained at a low endo-osmotic rate, without altering voltage (voltage was set at a constant 250V). Unlike method 3, stream 2 volume of methods 1 and 2 required continual monitoring and toping up.

Method 1 isolated 34.8% fibrinogen, while method 2 isolated 42.6% fibrinogen and method 3 isolated 53.5% fibrinogen from a stock cryo-precipitate solution (FIG. 12). Overall, method 2 and 3 appeared to be commercially suitable due to the high percentage recovery and decrease of the endo-osmosis rate.

The use of PVA1 during a fibrinogen isolation resulted in a 4× increase in the protein transfer rate in the apparatus (Table 1). Using PVA1 as a top restriction membrane, to reduce electro-endo-osmosis, resulted in an increase in protein transfer from 44.7% to 77.3%. These results also demonstrate using PVA1 can decrease or improve the recovery time. When using PA membranes, 32.5 mg fibrinogen was recovered after 120 min, while 36.1 mg of fibrinogen was recovered in 30 min using PVA1. Using PVA1 therefore allowed more fibrinogen to be removed in a quarter of the time.

TABLE 1
Comparison of protein transfer during fibrinogen isolation. The table
compares using PAM and PVAl during fibrinogen isolation.

| | | PVAl top |
|---|---|---|
| | Control | membrane |
| Total protein recovered | 24.3% | 31.3% |
| Total protein recovered after 30 | 44.7% | 77.3% |
| min | | |
| Recovery comparison | 32.5 mg/120 min | 36.1 mg/30 min |
| | (0.27 mg/min) | (1.20 mg/min) |
| Electro-endo-osmosis (mL/min) | 1.71 | 0.00 |

### Example 7

### Simultaneous Separation and Concentration of Bovine Prion Protein (PrP) of Bovine Brain Homogenate Using PVA1 Membrane

Another application for membrane-based electrophoresis involved the simultaneous separation and concentration of the bovine Prion Protein (PrP) of bovine brain homogenate, using a PVA1 membrane as a top restriction membrane separating stream 1 from the first electrode zone. Typically during separation experiments involving PrP, electro-endo-osmosis causes an increase in the volume of the starting material. However, with the introduction of PVA1 as a top restriction membrane, the electro-endo-osmosis rate was decreased.

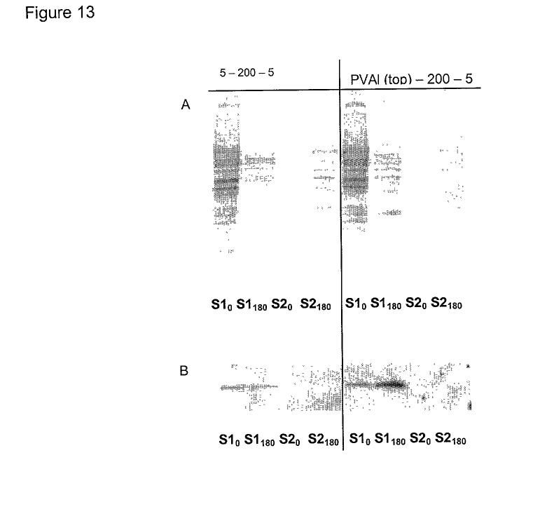

In FIG. 13, a comparison of a typical PrP separation and a separation and concentration of PrP using PVA1 has been provided. Part A of FIG. 13, an SDS-PAGE of the samples from the two electrophoresis experiments, demonstrates transfer of protein from stream 1 to stream 2. Part B of FIG. 13 is the corresponding western blot of the samples hybridized with anti-PrP R029 (Prionics, Switzerland). Normally, separation of PrP is carried out for 3 hours at 250V using a cartridge with a separation membrane of 200 kDa, and two restriction membranes of 5 kDa using Tris Borate buffer pH 9.0 (Part A, lanes 1-4), the conditions under which PrP remained in stream 1 (Part B, lanes 1-4). When using the same conditions, but replacing the top restriction membrane with PVA1 membrane, simultaneous separation and concentration of PrP from bovine brain homogenate was achieved.

The use of PVA1 resulted in a 5× decrease in the volume of the stream 1 at the end of the experiment and thus a stark increase in the concentration of PrP, as detected by the increase of intensity of the PrP band on the Western blot (Part B).

### Results Examples 1-7

The highest endo-osmotic rate was produced using a single stream configuration electrophoresis apparatus with a 10 kDa CTA membrane, in either symmetry. The identification of the configuration with the highest endo-osmotic rate allowed for experiments to manage this rate. Analyzing whether endo-osmosis was voltage dependent demonstrated that the rate of volume loss linearly increased as the voltage increased. Therefore, increasing the voltage of a system can reduce the effect of endo-osmosis, by electro-osmosis. The relationship between pH and endo-osmosis suggest that each buffer system had its own variables and that pH may need to be investigated on an individual application basis to obtain optimum separation and/or concentration.

To test whether the endo-osmotic rate could be managed with a charged membrane (CTA), a procedure with a high endo-osmotic rate was studied. The procedure with a high endo-osmotic rate was the isolation of fibrinogen from cryo-precipitate. Three experiments were used to study endo-osmosis management. The first experiment was a control which identified the endo-osmosis rate of a standard fibrinogen isolation run. The second experiment involved reducing the endo-osmotic rate by replacing the top PA membrane restriction with CTA. The final experiment utilized a second apparatus, in a single stream configuration (CTA top and PA membrane on the bottom), which managed the stream 1 volume of the first apparatus. Each apparatus had its own power supply. Therefore, the rate of electro-osmosis in apparatus 2 could be managed by varying the voltage (matching the electro-osmotic rate). The results of these experiments demonstrated that endo-osmotic rate of the stream 1 could be managed thereby increasing total recovery of fibrinogen and accelerating purification.

The control of the endo-osmotic rate also has application in investigations involving PrP. The use of PVA1 demonstrates a method for the simultaneous concentration and separation of PrP. This method has applications in product purification along with prion detection and diagnostics.

### Electro Endo-Osmosis Apparatus Configurations for Monoclonal Antibody/Recombinant Purifications/Concentration

The present invention is especially applicable to simultaneous purification and concentration of proteins which are grown by recombinant or tissue culture means and are produced in a dilute form in large liquid volumes. Use of the method and apparatus according to the present invention allows for numerous configurations where simultaneous purification and concentration/volume control can take place.

Purification procedures may take one of two general forms: transfer of target protein away from contaminants which are retained in the feed stream (sample) and transfer of contaminants away from the target protein which is retained in the feed stream (sample).

In the first form, as the target protein concentration falls, the rate of target protein transfer will also fall, resulting in slower purification. The contribution of endo-osmosis may also increase the feed stream volume, further slowing purification. The ability to concentrate or control the volume of the feed stream allows the transfer of target protein to be maintained at the highest possible rate.

In the second form, as the contaminant concentration in the feed stream falls, purification will also slow, prolonging purification time. The ability to concentrate the feed stream where product is accumulating will enhance the rate of purification by maintaining the transfer rate of contaminants from the target protein, simultaneously delivering a concentrated target protein.

Both these techniques are applicable with respect to any protein (or other compound) that is present in low concentrations in the feed stream, especially recombinant and monoclonal antibody (MAb) proteins which are routinely grown at concentrations between 5 and 100 ug/mL in tissue culture medium.

Several configurations of the membrane-based electrophoresis apparatus can be used to effect simultaneous purification and concentration of a product that is present at low concentrations in a large volume.

### Example 8

### Simultaneous Concentration and Partial Purification

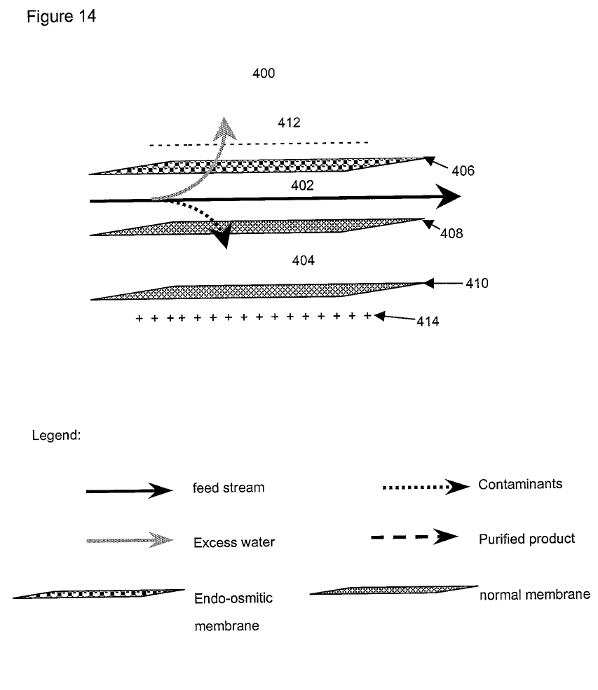

In a single apparatus 400 as shown in FIG. 14, having one feed stream 402 (stream 1) and a separation stream 404 (stream 2), a top restriction membrane 406 with electro-endo-osmosis properties is used to draw water from the large volume of dilute feed stream into a first electrode zone 412. The apparatus is further comprised of a normal membrane 408 which separates the sample stream from the separation stream and a normal membrane 410 which separates the separation stream from a second electrode zone 414. Conditions are chosen such that some, or ideally all contaminants are transferred to the separation stream while the target protein (and possibly some remaining contaminants) are concentrated by electro-endo-osmosis in the feed stream.

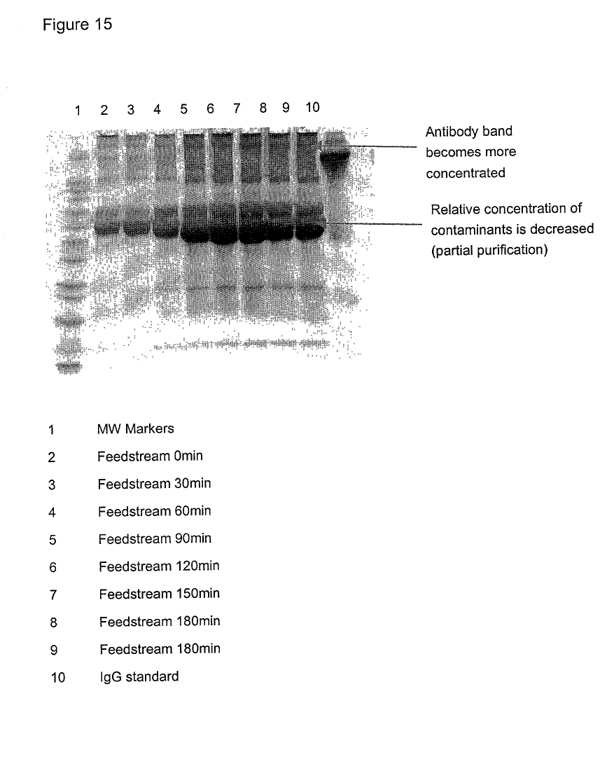

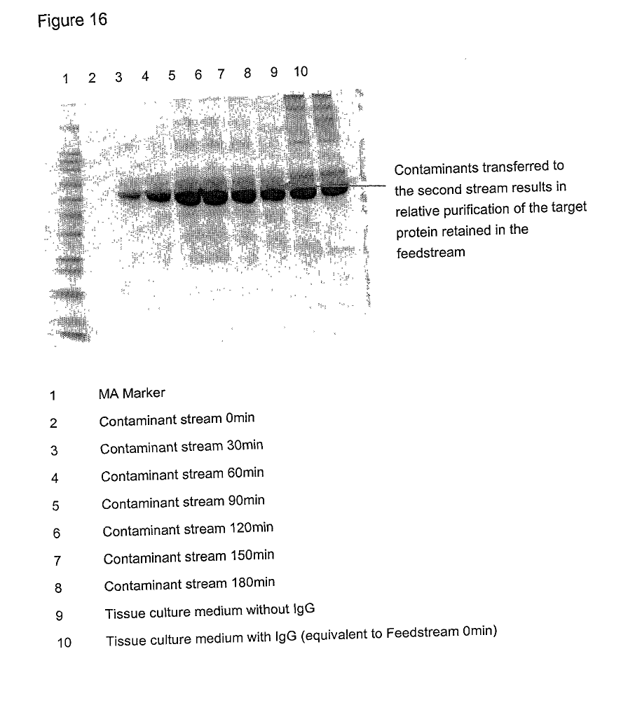

In an example of this method, a 130 mL feed stream was concentrated to 10 mL (13 fold concentration) in 180 minutes, while significant quantities of albumin and transferrin contaminants were removed to the second stream. Results of PAGE analysis are shown in FIG. 15 and FIG. 16. This example provided partial purification of the target and significant concentration of the product. The example provided was carried out with tissue culture supernatant containing 10% FCS. This configuration is even more suitable for serum-free medium where the target protein is a significant proportion of the total protein. This method could be improved with alterations to the separation membrane and buffer conditions, as well as the cut off of the electro-endo-osmosis membrane.

Antibody concentration was increased over 10-fold during a 3 hour period. Relative concentration of contaminants was decreased over this time by transferring contaminants to a second stream as shown in FIG. 16.

The data in FIG. 15 and FIG. 16 show that contaminants were selectively removed from the feed stream without loss of the target protein, indicating partial purification of the target protein.

### Example 9

### Simultaneous Concentration and Purification of Target Protein with Contaminant Depletion of Feed Stream and Electro-Endo-Osmosis Control of Feed Stream Volume

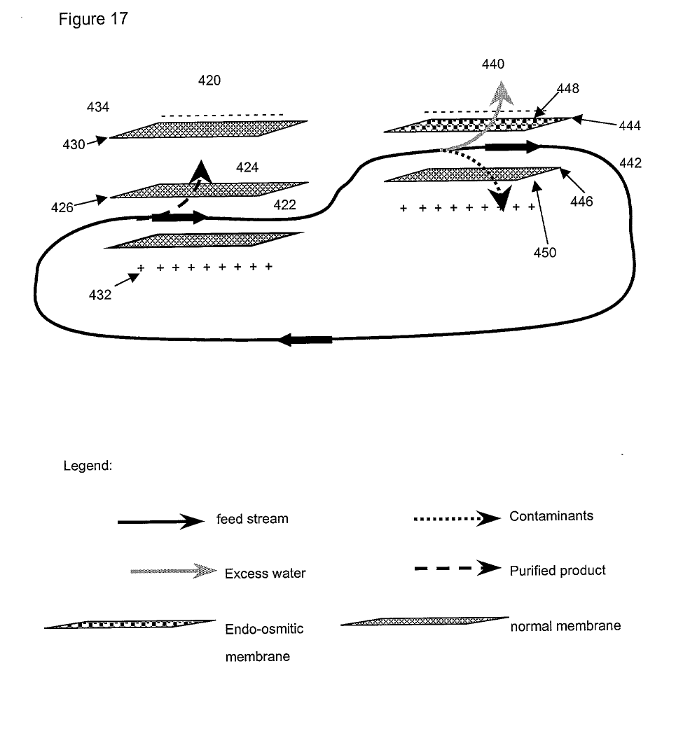

This example uses two apparati 420 and 440 as shown in FIG. 17. One apparatus 420 was configured to transfer target protein into a separate product stream away from contaminants that were retained in the feed stream. The first apparatus has one feed stream 422 (stream 1) containing a sample to be treated and a separation stream 424 (stream 2) into which a selected compound is transferred by electrophoresis. The first apparatus is comprised of a first normal membrane 426 which separates the feed stream from a first electrode zone 432, a normal membrane 428 which separates the feed stream from the separation stream, and a normal membrane 430 which separates the separation stream from a second electrode zone 434.

In a separate apparatus, a cartridge using an electro-endo-osmosis top restriction membrane 444 was used to concentrate the feed stream 442 to maintain the transfer rate of target protein in the first separation unit. Excess water was transferred to a first buffer stream or electrode zone 448. In the example given below, the second apparatus was also configured to allow transfer of contaminants from the feed stream through a normal membrane 446 into a second buffer stream or electrode zone 450 of the second instrument, thereby depleting the feed stream of contaminants.

In an example of this method, a 130 mL feed stream was concentrated to 100 mL over a period of 180 minutes, while albumin and transferrin contaminants were removed to the buffer stream of the second apparatus. This provided excellent purification of the target protein, significant concentration of the product by transferring the product to a small stream volume, but also allowed for cleaning and concentrating the feed stream to enhance target protein transfer. The example provided was carried out with tissue culture supernatant containing 10% fetal calf serum(FCS). This method could be enhanced through the use of a electro-endo-osmosis membrane capable of greater liquid transfer, or the use of an electro-endo-osmosis membrane capable of drawing liquid towards the positive electrode.

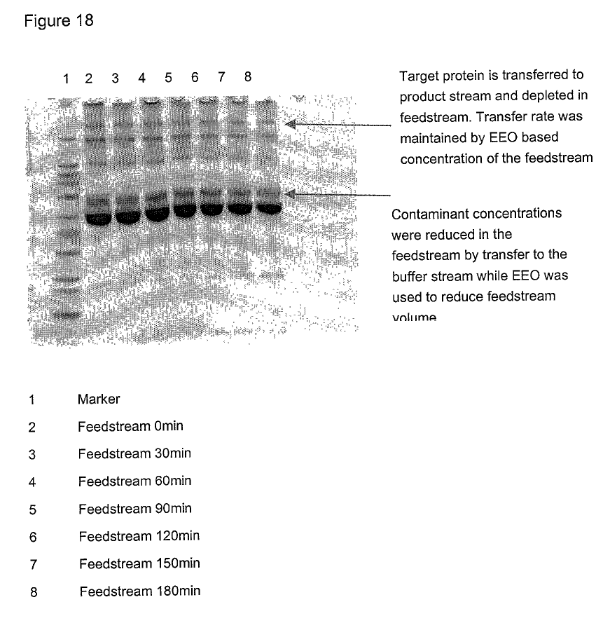

FIG. 18 shows PAGE analysis of results the above experiment. Feed stream was concentrated during the course of the experiment, but was also depleted of contaminant proteins. Contaminant depletion enhances the transfer of the target protein to the product stream by simplifying the contents of the feed stream.

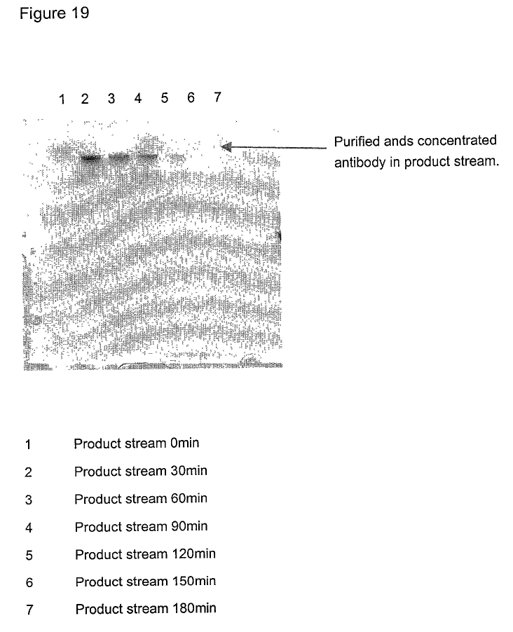

FIG. 19 shows PAGE of final purification results the above experiment. The target protein was purified and concentrated into the product stream. The transfer rate to the product stream was maintained by concentrating the feed stream. As the concentration of target in the feed stream was depleted, the transfer rate slowed unless the feed stream volume was reduced. This volume reduction would result in interference from the increased contaminant concentration unless the feed stream was also depleted of contaminants.

Alternative configurations where electro-endo-osmosis can be used to purify and concentrate target proteins from dilute starting materials

### Example 10

### Target is Transferred to Second Stream and Feed Stream is Concentrated

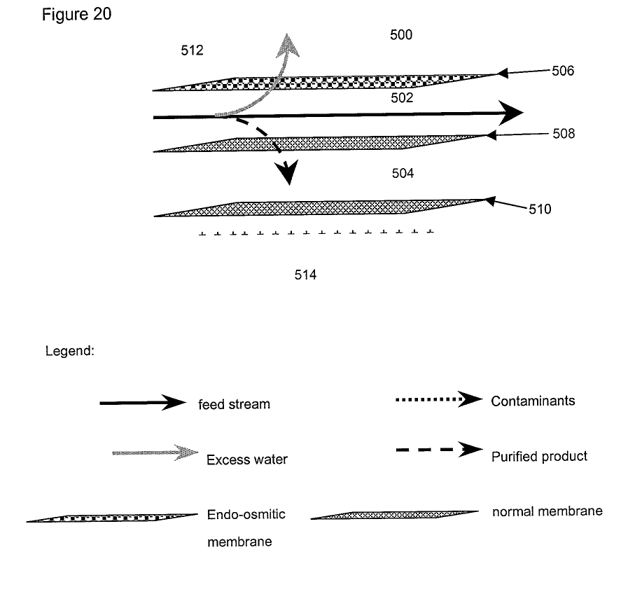

The single apparatus 500 configured as shown in FIG. 20,has one feed stream 502 (stream 1) containing a sample to be treated and a separation stream 504 (stream 2) into which a selected compound is transferred by electrophoresis. A top restriction membrane 506 with electro-endo-osmosis properties is used to draw water from the feed stream into a first buffer stream or electrode zone 512. The apparatus is further comprised of a normal membrane 508 which separates the feed stream from the separation stream and a normal membrane 510 which separates the separation stream from a second buffer stream or electrode zone 514. Conditions are chosen such that some, or ideally all of a selected compound is transferred to the separation stream while the sample is concentrated by electro-endo-osmosis in the feed stream to maintain flux rate of product stream.

### Example 11

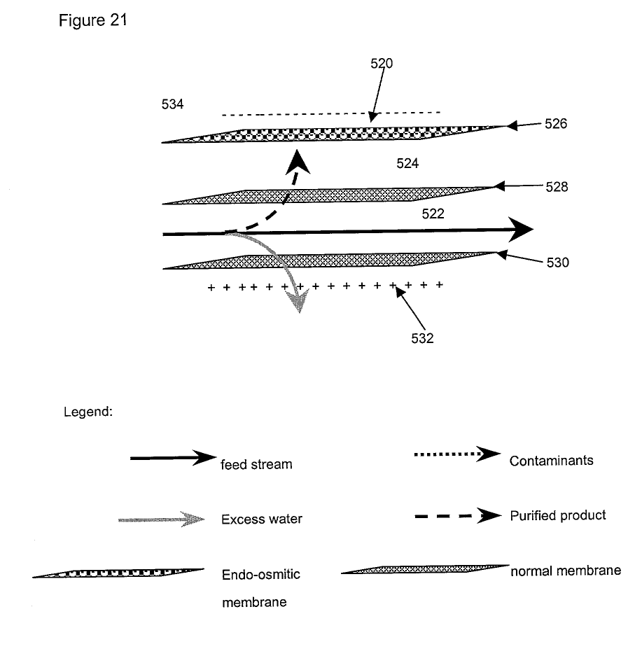

Transfer of product to stream 2 while concentrating and optionally purifying stream 1 with contaminants transferred to the buffer stream or an optional third stream The single apparatus 520 configured as shown in FIG. 21 has one feed stream 522 (stream 1) containing a sample to be treated and a separation stream 524 (stream 2) into which a selected compound is transferred by electrophoresis. A top restriction membrane 526 with electro-endo-osmosis properties is used to drive water from the feed stream into a first buffer stream or electrode zone 532. The apparatus is further comprised of a normal membrane 528 which separates the feed stream from the separation stream and a normal membrane 530 which separates the separation stream from a second buffer stream or electrode zone 534. Conditions are chosen such that some, or ideally all of a selected compound is transferred to the separation stream while the sample is concentrated by electro-endo-osmosis in the feed stream to maintain flux rate of compound in the feed stream.

### Example 12

### Use of Electro-Endo-Osmosis Membranes on Either Side of the Feed Stream to Enhance Concentration Effect, with Molecular Mass Cut-Off of Electro-Endo-Osmosis Membranes Selected to Allow for Contaminant Transfer away from the Target Protein which is Retained and Concentrated in the Center Feed Stream

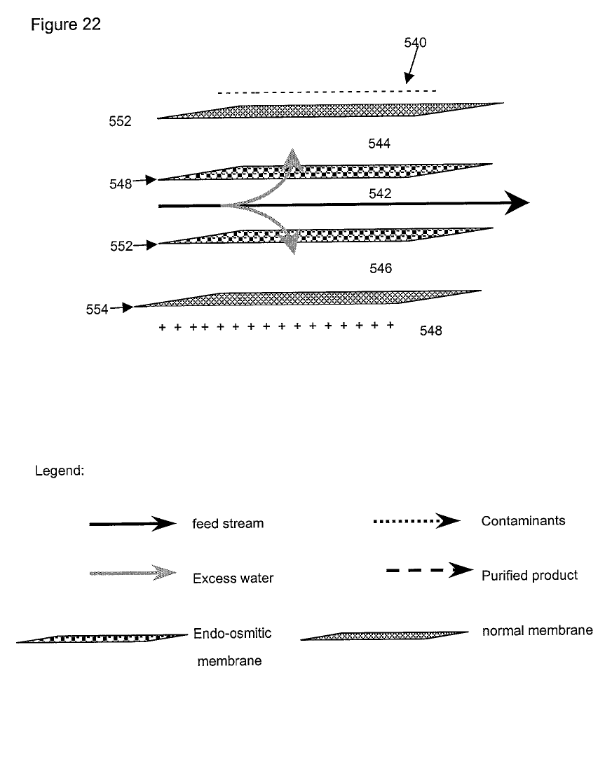

The single apparatus 540 configured as shown in FIG. 22 has one feed stream 542 (stream 1) containing a sample to be concentrated and cleaned, and upper and lower streams 544 and 546 (streams 2 and 3) into which water and unwanted contaminants are transferred by electrophoresis. Two restriction membranes 548 and 550 with electro-endo-osmosis properties form the feed stream and are used to drive water from the feed stream through to the upper and lower streams. The apparatus further includes a normal membrane 552 which separates the upper stream from a first electrode zone 556 and a normal membrane 554 which separates the lower stream from a second electrode zone 558. Conditions are chosen such that some, or ideally all contaminants are transferred to the upper or lower streams while the sample is concentrated by electro-endo-osmosis in the feed stream.

### Example 13

### Use of two Electrophoresis Apparatus for Separate Concentrating and Purifying Functions

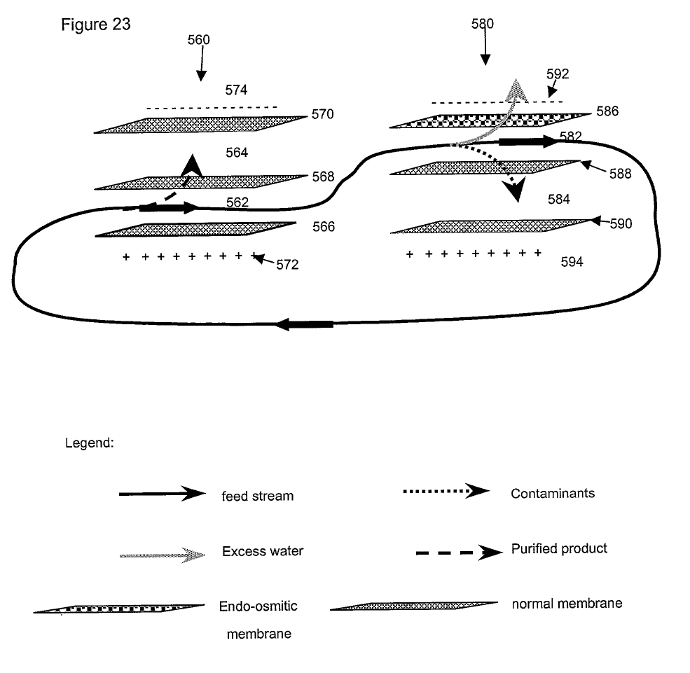

This example uses two apparati 560 and 580 as shown in FIG. 23. One apparatus is configured to transfer target protein into a separate product stream away from contaminants that were retained in the sample stream. The first apparatus has one feed stream 562 (stream 1) containing a sample to be treated and a separation stream 564 (stream 2) into which a selected compound is transferred by electrophoresis. The first apparatus is comprised of a first normal membrane 566 which separates the feed stream from a first electrode zone 572, a normal membrane 568 which separates the feed stream from the separation stream, and a normal membrane 570 which separates the separation stream from a second electrode zone 574.

The second apparatus is comprised of a cartridge using an electro-endo-osmosis top restriction membrane 586 and two normal membranes 588 and 590 forming two streams 582 and 584 to concentrate the sample stream, remove contaminants and to maintain the transfer rate of target protein in the first separation unit. The top restriction membrane separates the upper stream 582 from a first buffer stream or electrode zone 592. The second normal membrane 590 separates the lower stream 584 from a second buffer stream or electrode zone 594.

### Example 14

### Target Remains in the Feed Stream and is Concentrated

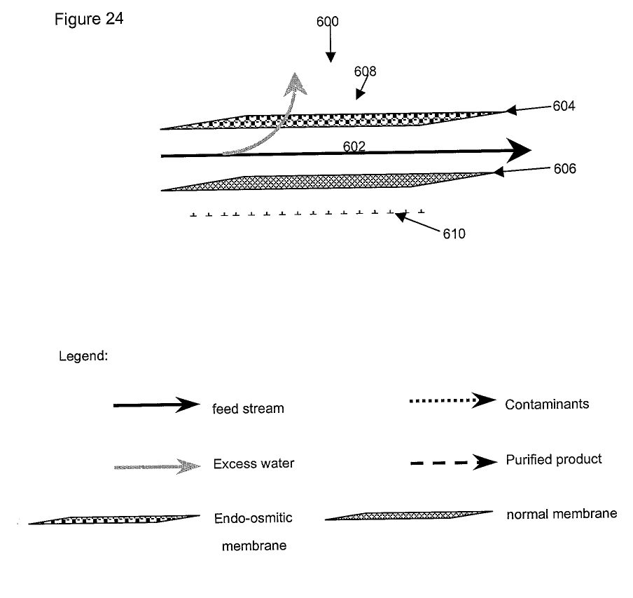

The single apparatus 600 configured as shown in FIG. 24 has one feed stream (stream 1) 602 containing a sample to be concentrated and cleaned. One restriction membrane 604 with electro-endo-osmosis properties and is used to drive water from the feed stream through to an electrode zone 608 to form a concentrated sample. A normal membrane 606 separates the feed stream from a second electrode zone 610.

Many other configurations are possible depending on target protein and feed stream contaminant profiles, using different membrane chemistry and buffer combinations that draw bulk liquid in the required directions and molecular mass cut-off of membranes tuned for optimal transfer of contaminants or target proteins.

It will be appreciated by persons skilled in the art that numerous variations and/or modifications may be made to the invention as shown in the specific embodiments without departing from the spirit or scope of the invention as broadly described. The present embodiments are, therefore, to be considered in all respects as illustrative and not restrictive. Other features and aspects of this invention will be appreciated by those skilled in the art upon reading and comprehending this disclosure. Such features, aspects, and expected variations and modifications of the reported results and examples are clearly within the scope of the invention where the invention is limited solely by the scope of the following claims.

What is claimed is:

1. An electrophoresis apparatus comprising:
a first electrode in a first electrode zone;
a second electrode in a second electrode zone, wherein the second electrode is disposed relative to the first electrode so as to be adapted to generate an electric field in an electric field area therebetween upon application of a selected electric potential between the first and second electrodes;
a first membrane disposed in the electric field area;
a second membrane disposed between the first electrode zone and the first membrane so as to define a first interstitial volume therebetween, wherein the first interstitial volume is separated from the first and second electrode zones by the first and second membranes, and wherein at least one of the membranes is a barrier membrane capable of controlling substantial bulk movement of liquid under the influence of an electric field; and
means adapted to communicate fluids to the first electrode zone, the second electrode zone, and the first interstitial volume wherein at least one of the fluids contains a sample constituent, wherein the application of the selected electric potential causes at least one of
at least a portion of any liquid within the sample constituent to migrate through at least one membrane into an adjacent electrode zone, and
at least a portion of the sample constituent to migrate through at least one membrane into the first interstitial volume, and
wherein the at least one barrier membrane controls substantial bulk movement of liquid into and out of the first interstitial volume so as to obtain at least a partially concentrated product in the first interstitial volume.

2. The apparatus according to claim 1 further comprising means adapted to receive a selected voltage and means adapted to apply a selected electric potential corresponding thereto across at least the electric field area.

3. The apparatus according to claim 1 further comprising means adapted for removing any heat generated in the apparatus.

4. The apparatus according to claim 1 wherein the at least one barrier membrane is an inducible electro-endo-osmotic membrane.

5. The apparatus according to claim 4 wherein the inducible electro-endo-osmotic membrane is selected from the group consisting of cellulose tri-acetate, polyvinyl alcohol, poly(vinyl alcohol) cross-linked with glutaraldehyde, and combinations thereof.

6. The apparatus according to claim 4 wherein the inducible electro-endo-osmotic membrane has a defined pore size.

7. The apparatus according to claim 6 wherein the inducible electro-endo-osmotic membrane has a defined pore size ranging from about 5%Da to about 1000 kDa.

8. The apparatus according to claim 1 wherein the at least one barrier membrane is adjacent to at least one of the first and second electrode zones.

9. The apparatus according to claim 1 wherein at least one of membranes is an electrophoresis separation membrane having a defined pore size.

10. The apparatus according to claim 9 wherein the electrophoresis separation membrane is made from polyacrylamide.

11. The apparatus according to claim 10 wherein the electrophoresis separation membrane has a defined pore size ranging from about 1 to about 2000 kDa.

12. An electrophoresis apparatus comprising:
a first electrode in a first electrode zone;
a second electrode in a second electrode zone, wherein the second electrode disposed relative to the first electrode so as to be adapted to generate an electric field in an electric field area therebetween upon application of a selected electric potential between the first and second electrodes;
a first membrane disposed in the electric field area;
a second membrane disposed between the first electrode zone and the first membrane so as to define a first interstitial volume therebetween;
a third membrane disposed between a second electrode zone and the first membrane so as to define a second interstitial volume therebetween, wherein the first interstitial volume is separated from the first electrode zone by the second membrane and the second interstitial volume is separated from the second electrode zone by the third membrane, and wherein at least one of the membranes is a barrier membrane capable of controlling substantial bulk movement of liquid under the influence of an electric field; and
means adapted to communicate fluids to the first electrode zone, the second electrode zone, the first interstitial volume, and the second interstitial volume, wherein at least one of the fluids contains a sample constituent, wherein the application of the selected electric potential causes at least one of
at least a portion of any liquid within the sample constituent to migrate through at least one membrane into an adjacent electrode zone, and
at least a portion of the sample constituent to migrate through at least one membrane into at least one of the interstitial volumes, and
wherein the at least one barrier membrane controls substantial bulk movement of any liquid into and out of at least one of the interstitial volumes so as to obtain at least a partially concentrated product in at least one of the interstitial volumes.

13. The apparatus according to claim 12 further comprising means adapted to receive a selected voltage and means adapted to apply a selected electric potential corresponding thereto across at least the electric field area.

14. The apparatus according to claim 12 wherein the apparatus further comprises means adapted for removing any heat generated in the apparatus.

15. The apparatus according to claim 12 wherein the at least one barrier membrane is an inducible electro-endo-osmotic membrane.

16. The apparatus according to claim 15 wherein the inducible electro-endo-osmotic membrane is selected from the group consisting of cellulose tri-acetate, polyvinyl alcohol, poly(vinyl alcohol) cross-linked with glutaraldehyde, and combinations thereof.

17. The apparatus according to claim 16 wherein the inducible electro-endo-osmotic membrane has a defined pore size.

18. The apparatus according to claim 17 wherein the inducible electro-endo-osmotic membrane has a defined pore size ranging from about 5 kDa to about 1000 kDa.

19. The apparatus according to claim 12 wherein the at least one barrier membrane is adjacent to at least one of the first and second electrode zones.

20. The apparatus according to claim 12 wherein at least one of membranes is an electrophoresis separation membrane having a defined pore size.

21. The apparatus according to claim 20 wherein the electrophoresis separation membrane is made from polyacrylamide.

22. The apparatus according to claim 21 wherein the electrophoresis separation membrane has a defined pore size ranging from about 1 to about 2000 kDa.

23. An electrophoresis system comprising:
a first electrode in a first electrode zone;
a second electrode in a second electrode zone, wherein the second electrode disposed relative to the first electrode so as to be adapted to generate an electric field in a first electric field area therebetween upon application of a selected electric potential between the first and second electrodes;
a first membrane disposed in the first electric field area;
a second membrane disposed between the first electrode zone and the first membrane so as to define a first interstitial volume therebetween;
a third membrane disposed between a second electrode zone and the first membrane so as to define a second interstitial volume therebetween, wherein the first interstitial volume is separated from the first electrode zone by the second membrane and the second interstitial volume is separated from the second electrode zone by the third membrane;
means adapted to communicate fluids to the first electrode zone, the second electrode zone, the first interstitial volume, and the second interstitial volume, wherein at least one of the fluids contains a sample constituent, wherein the application of the first selected electric potential causes at least a portion of the sample constituent to migrate through at least one membrane into at least one of the interstitial volumes to form a partially separated sample;
a third electrode in a third electrode zone;
a fourth electrode in a fourth electrode zone, wherein the third electrode disposed relative to the fourth electrode so as to be adapted to generate an electric field in a second electric field area therebetween upon application of a second selected electric potential between the third and fourth electrodes;
a fourth membrane disposed in the second electric field area;
a fifth membrane disposed between the third electrode zone and the fourth membrane so as to define a third interstitial volume therebetween, wherein the third interstitial volume is separated from the third and fourth electrode zones by the fourth and fifth membranes, wherein at least one of the fourth and fifth membranes is a barrier membrane capable of controlling substantial bulk movement of liquid under the influence of an electric field; and
means adapted to communicate fluids to the third electrode zone, the fourth electrode zone, and the third interstitial volume, wherein at least one of the fluids contains at least a partially separated sample from at least one of the first and second interstitial volumes, wherein the application of the selected electric potential causes at least one of
at least a portion of any liquid within the partially separated sample to migrate through at least one membrane into an adjacent electrode zone, and
at least a portion of the first partially concentrated product to migrate through at least one membrane into third the interstitial volumes, and
wherein the at least one barrier membrane controls substantial bulk movement of any liquid into and out of the third interstitial volumes so as to obtain at least a partially concentrated product in the third interstitial volume.

24. The apparatus according to claim 23 further comprising means adapted to receive a first selected voltage and means adapted to apply a first selected electric potential corresponding thereto across the first electric field area; and means adapted to receive a second selected voltage and means adapted to apply a second selected electric potential corresponding thereto across the second electric field area.

25. The apparatus according to claim 23 wherein the apparatus further comprises means adapted for removing any heat generated in the apparatus.

26. The apparatus according to claim 23 wherein the at least one barrier membrane is an inducible electro-endo-osmotic membrane.

27. The apparatus according to claim 26 wherein the inducible electro-endo-osmotic membrane is selected from the group consisting of cellulose tri-acetate, polyvinyl alcohol, poly(vinyl alcohol) cross-linked with glutaraldehyde, and combinations thereof.

28. The apparatus according to claim 27 wherein the inducible electro-endo-osmotic membrane has a defined pore size.

29. The apparatus according to claim 28 wherein the inducible electro-endo-osmotic membrane has a defined pore size ranging from about 5 to about 1000 kDa.

30. The apparatus according to claim 23 wherein the at least one barrier membrane is adjacent to at least one of the first and second electrode zones.

31. The apparatus according to claim 23 wherein at least one of membranes is an electrophoresis separation membrane having a defined pore size.

32. The apparatus according to claim 31 wherein the electrophoresis separation membrane is made from polyacrylamide.

33. The apparatus according to claim 32 wherein the electrophoresis separation membrane has a defined pore size ranging from about 1 to about 2000 kDa.

34. A method for concentrating a sample, the method comprising:
communicating fluids to a first electrode zone and a second electrode zone, wherein the first and second electrode zones each contain an electrode and the second electrode zone is disposed relative to the first electrode zone so as to be adapted to generate an electric field in an electric field area therebetween upon application of a selected electric potential between the first and second electrodes;
communicating a fluid to a first interstitial volume defined by a first membrane disposed in the electric field area and a second membrane disposed between the first electrode zone and the first membrane, wherein the first interstitial volume is separated from the first and second electrode zones by the first and second membranes, and wherein at least one membrane is a barrier membrane capable of controlling substantial bulk movement of liquid under the influence of an electric field, and wherein at least one of the fluids communicated to the electrode zones and the first interstitial volume contains a sample constituent; and
applying a selected electric potential across at least the electric field area, wherein the application of the selected electric potential causes at least one of
at least a portion of any liquid within the sample constituent to migrate through at least one membrane into an adjacent electrode zone, and
at least a portion of the sample constituent to migrate through at least one membrane into the first interstitial volume, and
wherein the at least one barrier membrane controls substantial bulk movement of any liquid into and out of the first interstitial volume so as to obtain at least a partially concentrated product in the first interstitial volume.

35. The method according to claim 34 wherein the method further comprises collecting the concentrated product from the first interstitial volume.

36. A method for moving at least one component from a sample while controlling the bulk movement of liquid, the method comprising:
communicating fluids to a first electrode zone and a second electrode zone, wherein the first and second electrode zones each contain an electrode and the second electrode zone is disposed relative to the first electrode zone so as to be adapted to generate an electric field in an electric field area therebetween upon application of a selected electric potential between the first and second electrodes;
communicating fluids to a first interstitial volume and a second interstitial volume, wherein the first interstitial volume is defined by a first membrane disposed in the electric field area and a second membrane disposed between the first electrode zone and the first membrane, wherein the second interstitial volume is defined by the first membrane and a third membrane disposed between the first membrane and the second electrode zone, wherein the first interstitial volume is separated from the first electrode zone by the second membrane and the second interstitial volume is separated from the second electrode zone by the third membrane, and wherein at least one membrane is a barrier membrane capable of controlling substantial bulk movement of liquid under the influence of an electric field, and wherein at least one of the fluids communicated to the electrode zones and interstitial volumes contains a sample constituent; and
applying a selected electric potential across at least the electric field area, wherein the application of the selected electric potential causes at least one of
at least a portion of any liquid within the sample constituent to migrate through at least one membrane into an adjacent electrode zone, and
at least a portion of the sample constituent to migrate through at least one membrane into at least one of the interstitial volumes, and
wherein the at least one barrier membrane controls substantial bulk movement of any liquid into and out of at least one of the interstitial volumes so as to obtain at least a partially concentrated product in at least one of the interstitial volumes.

37. The method according to claim 36 wherein the method further comprises collecting a concentrated product from at least one of the first and second interstitial volumes.

38. A method for moving at least one component from a sample while controlling the bulk movement of liquid, the method comprising:
communicating fluids to a first electrode zone and a second electrode zone, wherein the first and second electrode zones each contain an electrode and the second electrode zone is disposed relative to the first electrode zone so as to be adapted to generate an electric field in a first electric field area therebetween upon application of a selected electric potential between the first and second electrodes;
communicating fluids to a first interstitial volume and a second interstitial volume, wherein the first interstitial volume is defined by a first membrane disposed in the first electric field area and a second membrane disposed between the first electrode zone and the first membrane, wherein the second interstitial volume is defined by the first membrane and a third membrane disposed between the first membrane and the second electrode zone, wherein the first interstitial volume is separated from the first electrode zone by the second membrane and the second interstitial volume is separated from the second electrode zone by the third membrane, and wherein at least one of the fluids communicated to the electrode zones and interstitial volumes contains a sample constituent;
applying a selected electric potential across at least the first electric field area, wherein the application of the first selected electric potential causes at least a portion of the sample constituent to migrate through at least one membrane into at least one of the interstitial volumes to form a partially separated sample;
collecting the partially separated sample from at least one of the first and second interstitial volumes;
communicating fluids to a third electrode zone and a fourth electrode zone, wherein the third and fourth electrode zones each contain an electrode and the fourth electrode zone is disposed relative to the third electrode zone so as to be adapted to generate an electric field in a second electric field area therebetween upon application of a selected electric potential between the third and fourth electrodes;
communicating a fluid to a third interstitial volume defined by a third membrane disposed in the second electric field area and a fifth membrane disposed between the third electrode zone and the fourth membrane, wherein the first interstitial volume is separated from the third and fourth electrode zones by the fourth and fifth membranes, wherein at least one of the fourth and fifth membranes is a barrier membrane capable of controlling substantial bulk movement of liquid under the influence of an electric field, and wherein at least one of the fluids communicated to the electrode zones and the third interstitial volume contains at least the concentrated sample from at least one of the first and second interstitial volumes; and
applying a selected electric potential across at least the second electric field area, wherein the application of the selected electric potential causes at least one of
at least a portion of any liquid within the first partially concentrated product to migrate through at least one membrane into an adjacent electrode zone, and
at least a portion of the partially concentrated sample to migrate through at least one membrane into third the interstitial volumes, and
wherein the at least one barrier membrane controls substantial bulk movement of any liquid into and out of the third interstitial volumes so as to obtain at least a partially concentrated product in the third interstitial volume.

39. The method according to claim 38 wherein the method further comprises collecting the concentrated product from the third interstitial volume.
